(19) United States
(12) Patent Application Publication
(10) Pub. No.: US 2016/0204254 A1
(43) Pub. Date: Jul. 14, 2016

(54) SEMICONDUCTOR DEVICE

(71) Applicant: TOYOTA JIDOSHA KABUSHIKI KAISHA, Toyota-shi (JP)

(72) Inventors: Hidemoto TOMITA, Toyota-shi (JP); Masakazu KANECHIKA, Nagakute-Shi (JP); Hiroyuki UEDA, Nagakute-shi (JP)

(73) Assignee: TOYOTA JIDOSHA KABUSHIKI KAISHA, Toyota-shi (JP)

(21) Appl. No.: 14/965,463

(22) Filed: Dec. 10, 2015

(30) Foreign Application Priority Data
Jan. 14, 2015 (JP) 2015-004733

(51) Int. Cl. H01L 29/78; H01L 29/66; H01L 29/778; H01L 29/20; H01L 29/205

(52) U.S. Cl. CPC H01L 29/7843; H01L 29/2003; H01L 29/205; H01L 29/7787; H01L 29/66462

(57) ABSTRACT

A semiconductor device includes a hetero junction structure including an electron transport layer of GaN and an electron supply layer of Inₓ₁Al_{y1}Ga_{1-x1-y1}N (0≦x1≦1, 0≦y1≦1, 0≦1−x1−y1<1), source and drain electrodes provided above an surface of the electron supply layer, a p-type layer of Inₓ₂Al_{y2}Ga_{1-x2-y2}N (0≦x2≦1, 0≦y2≦1, 0≦1−x2−y2≦1) provided above the surface of the electron supply layer and between the source electrode and the drain electrode, a gate electrode provided to be electrical contact with the p-type layer, and an insulation layer covering at least one of the surface of the electron supply layer exposed between the source electrode and the p-type layer and the surface of the electron supply layer exposed between the drain electrode and the p-type layer, wherein positive charges are fixed in at least a part of the insulation layer.

### CROSS-REFERENCE TO RELATED APPLICATION

This application claims priority to Japanese Patent Application No. 2015-004733 filed on Jan. 14, 2015, the contents of which are hereby incorporated by reference into the present application.

### TECHNICAL FIELD

The present specification discloses a semiconductor device that utilizes a two-dimensional electron gas generated at a hetero junction interface of nitride semiconductor layers and is adjusted to have normally-off characteristics.

DESCRIPTION OF RELATED ART

When an Inₓ₁Al_{y1}Ga_{1-x1-y1}N (0≦x1≦1, 0≦y1≦1, 0≦1−x1−y1<1) layer is stacked on a GaN layer, a two-dimensional electron gas is generated in a region of the GaN layer along a hetero junction interface. In the present specification, the GaN layer where the two-dimensional electron gas is generated is referred to as an electron transport layer, and the Inₓ₁Al_{y1}Ga_{1-x1-y1}N layer that generates the two-dimensional electron gas is referred to as an electron supply layer. The electron supply layer may contain Indium (In) or may not contain In. Similarly, the electron supply layer may contain Aluminum (Al) or may not contain Al. However, the electron supply layer needs to contain at least one of In and Al, and is not configured only with GaN. When a source electrode and a drain electrode are provided above a surface of the electron supply layer and the drain electrode is spaced from the source electrode, it is possible to realize a semiconductor device in which a source-drain resistance is decreased by the two-dimensional electron gas.

Depending on application purposes of a semiconductor device, one may wish to adjust the semiconductor device to have the normally-off characteristics. A technology has been developed to this end, in which a p-type layer is provided above a part of a surface of an electron supply layer exposed between a source electrode and a drain electrode, an example of which is disclosed in Injun Hwang et al. ISPSD (2012) p41 and Y. Uemoto et al. IEEE Trans. On Electron Devices Vol. 54 (2007) p3393. When the p-type layer is provided, a depletion layer spreads from an interface between the p-type layer and the electron supply layer toward the electron transport layer, and the hetero junction interface in a range opposite to the p-type layer is depleted, resulting in that the two-dimensional electron gas disappears. The semiconductor device is no longer in a state where the two-dimensional electron gas provides electrical conduction between the source and the drain, resulting in a high source-drain resistance. In this technology, a gate electrode is provided above a surface of the p-type layer. When a positive voltage is applied to the gate electrode, the depletion layer that extends from the p-type layer disappears, the two-dimensional electron gas is regenerated, and the semiconductor device is brought into a state where the two-dimensional electron gas provides the electrical conduction between the source and the drain, resulting in a low source-drain resistance. The semiconductor device can thus be adjusted to have the normally-off characteristics.

### BRIEF SUMMARY OF INVENTION

The semiconductor device adjusted to have the normally-off characteristics with the above-described technology still has a problem of a high on-resistance. The present specification discloses a technology for decreasing the on-resistance of the semiconductor device adjusted to have the normally-off characteristics with the above-described technology.

A semiconductor device disclosed in the present specification comprises a hetero junction structure including an electron transport layer of GaN and an electron supply layer of Inₓ₁Al_{y1}Ga_{1-x1-y1}N (0≦x1≦1, 0≦y1≦1, 0≦1−x1−y1<1) . A nitride semiconductor layer that forms the electron supply layer contains at least one of In and Al, and therefore is not GaN. Some nitride semiconductors that contain Gallium (Ga) and contain one or both of In and Al, have a bandgap larger than that of GaN, and when such a nitride semiconductor is used as an electron supply layer, a two-dimensional electron gas is generated at the hetero junction interface between the electron transport layer and the electron supply layer. In the semiconductor device disclosed in the present specification, a source electrode and a drain electrode are provided above a surface of the electron supply layer, the drain electrode being spaced from the source electrode. A p-type layer of Inₓ₂Al_{y2}Ga_{1-x2-y2}N (0≦x2≦1, 0≦y2≦1, 0≦1−x2−y2≦1) is provided above the surface of the electron supply layer and between the source electrode and the drain electrode. It suffices for the p-type layer to be a p-type layer that can be provided above the surface of the electron supply layer, and to be a nitride semiconductor that contains at least one of In, Al, and Ga. A gate electrode is provided to be electrical contact with the p-type layer. The surface of the electron supply layer is exposed between the source electrode and the p-type layer, and between the drain electrode and the p-type layer, and the exposed surface is covered by an insulation layer. The semiconductor device disclosed in the present specification includes an insulation layer, positive charges being fixed in at least a part of the insulation layer. The present technology may be applied to between the source electrode and the p-type layer, or between the drain electrode and the p-type layer, or may be applied to both of between the source electrode and the p-type layer and between the drain electrode and the p-type layer. The present technology is preferably applied to both between the source electrode and the p-type layer and between the drain electrode and the p-type layer. However, even if it is exclusively applied to one of them, the on-resistance can be decreased. The present technology may be applied to an entire region between the source electrode and the p-type layer, or to a part of that region. Similarly, the present technology may be applied to an entire region between the drain electrode and the p-type layer, or to a part of that region.

For example, if an insulation layer that covers the electron supply layer between the source electrode and the p-type layer is positively charged, electrons are induced at the hetero junction interface in a range opposite to the insulation layer, resulting in an increase in concentration of the two-dimensional electron gas and a decrease in the on-resistance. If an insulation layer that covers the electron supply layer between the drain electrode and the p-type layer is positively charged, electrons are induced at the hetero junction interface in a range opposite to the insulation layer, resulting in an increase in concentration of the two-dimensional electron gas and a decrease in the on-resistance. If the present technology is applied to both between the source electrode and the p-type layer and between the drain electrode and the p-type layer, both effects are obtained together, which further decreases the on-resistance.

The above-described technology is effective in a case where it is applied to a technology in which a p-type wide-region layer is formed above the surface of the electron supply layer in a wide range, and a part of the p-type wide-region layer is etched to define a range where the p-type layer is formed. When the part of the p-type wide-region layer is etched, the surface of the electron supply layer is exposed in that etched range. An etching damage is therefore exerted on the surface of the electron supply layer. It seems that the source-drain resistance is determined by a two-dimensional electron gas generated at the hetero junction interface, and that the surface of the electron supply layer has no influence on the source-drain resistance. However, it has actually been found that, if an etching damage is exerted on the surface of the electron supply layer, the electron supply layer is electrically charged to cause a decrease in the concentration of the two-dimensional electron gas generated at the hetero junction interface. According to the present technology, the effect of the etching damage that causes the decrease in the concentration of the two-dimensional electron gas can be compensated for by the effect of the positively charged insulation layer that causes the increase in the concentration of the two-dimensional electron gas, and consequently the on-resistance can be decreased.

As described above, the present technology shows its usefulness not only in the case where it is applied to both between the source electrode and the p-type layer and between the drain electrode and the p-type layer, but also in the case where it is exclusively applied to one of them. Similarly, the present technology shows its usefulness not only in the case where it is applied to the entire region of the electron supply layer exposed between the drain electrode and the p-type layer, but also in the case where it is applied to a part of that region. If the present technology is applied to a part of that region, it is preferable to use an insulation layer where positive charges are fixed in a drain electrode side of the insulation layer and are not fixed in a p-type layer side of the insulation layer. In this case, the on-resistance can be decreased with a withstand voltage maintained.

Similarly, the present technology may also be applied to a part of the exposed region of the electron supply layer that is exposed between the source electrode and the p-type layer. If the present technology is applied to a part of the exposed region, it is preferable to use an insulation layer where positive charges are fixed in a source electrode side of the insulation layer and are not fixed in a p-type layer side of the insulation layer. In this case, the on-resistance can be decreased with a withstand voltage maintained.

Various technologies may be utilized for a method of manufacturing the insulation layer where positive charges are fixed. For example, if the electron supply layer contains Ga, and a high-temperature treatment is applied to the surface thereof to form a SiO₂ layer, a part of Ga contained in the electron supply layer is captured by and fixed in the SiO₂ layer. It is thus possible to obtain an insulation layer where positively charged Ga ions are in a dispersed form within the SiO₂ layer.

According to the present technology, the problem of an increase in the on-resistance due to the normally-off features imparted by the p-type layer is overcome, and it is possible to realize a normally-off semiconductor device having a low on-resistance.

### BRIEF DESCRIPTION OF DRAWINGS

FIG. 1 is a cross section of a semiconductor device according to a first embodiment;

FIG. 2 is a cross section of a semiconductor device according to a second embodiment;

FIG. 3 is a cross section of a semiconductor device according to a third embodiment; and

FIG. 4 is a cross section of a semiconductor device according to a fourth embodiment.

### DETAILED DESCRIPTION OF INVENTION

Some of the features of the technology disclosed in the present specification will hereinafter be summarized. Note that each of the items described below individually has a technological usefulness.

### Feature 1

An electron transport layer is formed of GaN, and an electron supply layer is formed of AlGaN.

### Feature 2

An insulation layer is formed of an SiO₂ layer. The SiO₂ layer is formed in a temperature range in which Ga in. AlGaN that forms the electron supply layer moves into the SiO₂ layer.

### Feature 3

A distance between a source electrode and a p-type layer<a distance between a drain electrode and the p-type layer, and an insulation layer between the source electrode and the p-type layer is positively charged in its entire region, whereas an insulation layer between the drain electrode and the p-type layer is positively charged in its drain electrode side and is not positively charged in its p-type layer side.

### Feature 4

GaN is used for the electron transport layer, and a nitride semiconductor that contains Ga and at least one of In and Al, and has a bandgap larger than that of GaN is used for the electron supply layer. In other words, Inₓ₁Al_{y1}Ga_{1-x1-y1}N (0≦x1≦1, 0≦y1≦1, 0≦1−x1−y1<1) is used for the electron supply layer.

### Feature 5

GaN is used for the electron transport layer, and a nitride semiconductor that contains Al and Ga and has a bandgap larger than that of GaN is used for the electron supply layer. In other words, Inₓ₁Al_{y1}Ga_{1-x1-y1}N (0≦x1≦1, 0≦y1≦1, 0≦1−x1−y1<1) is used for the electron supply layer.

### First Embodiment

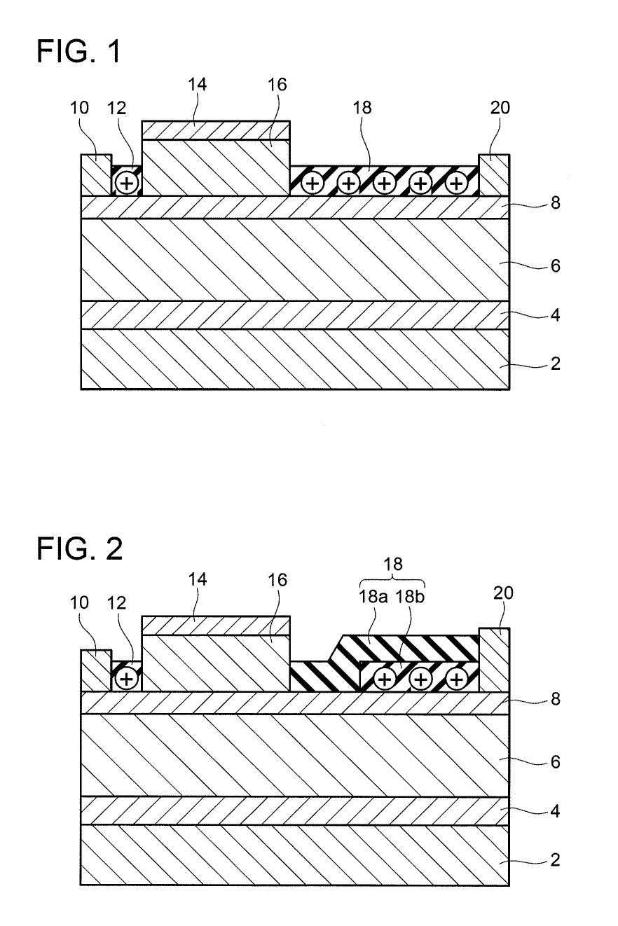

FIG. 1 is a cross section of a semiconductor device (normally-off-type field-effect transistor) of a first embodiment, where a buffer layer 4 is crystal-grown on a substrate 2, an i-type GaN layer 6 is crystal-grown on the buffer layer 4, and an i-type Al_{y1}Ga_{1-y1}N layer 8 (0<y1 <1) is crystal-grown on the i-type GaN layer 6. In the present embodiment, y1=0.18, and a film thickness of the layer 8 is 20 nm. At a hetero junction interface where the AlGaN layer 8 that contains Al is crystal-grown above the GaN layer 6 that does not contain Al, since a bandgap of the AlGaN layer 8 is wider than that of the GaN layer 6, a two-dimensional electron gas is generated in a region of the GaN layer 6 that faces the hetero junction interface. In the present embodiment, the GaN layer 6 where the two-dimensional electron gas is generated is referred to as an electron transport layer, and the AlGaN layer 8 that generates the two-dimensional electron gas is referred to as an electron supply layer. A source electrode 10 and a drain electrode 20 are provided on a surface of the electron supply layer 8. The source electrode 10 and the drain electrode 20 are provided to be spaced from each other. The electron supply layer 8 in a range interposed between the source electrode 10 and the hetero junction interface, and the electron supply layer 8 in a range interposed between the drain electrode 20 and the hetero junction interface have a low resistance because metals that form the electrodes 10, 20 is diffused or the like, for example.

A p-type Al_{y2}Ga_{1-y2}N layer 16 (0<y2<1, hereinafter referred to as “p-type layer 16”) is provided on the surface of the electron supply layer 8 in a range between the source electrode 10 and the drain electrode 20, and a gate electrode 14 is provided on a surface of the p-type layer 16. The gate electrode 14 is formed of a metal.

In a case where the p-type layer 16 is provided on the surface of the electron supply layer 8, and while no voltage is applied to the gate electrode 14, a depletion layer spreads from an interface between the p-type layer 16 and the electron supply layer 8 toward the electron transport layer 6 through the electron supply layer 8, the hetero junction interface in a range opposite to the p-type layer 16 is depleted, and the two-dimensional electron gas disappears. Electrical conduction between the source electrode 10 and the drain electrode 20 cannot be provided by the two-dimensional electron gas, which results in a high source-drain resistance. When a positive voltage is applied to the gate electrode 14, the depletion layer that extends from the p-type layer 16 disappears, the two-dimensional electron gas is regenerated, and the two-dimensional electron gas provides the electrical conduction between the source electrode 10 and the drain electrode 20, which results in a low source-drain resistance. Since the electron transport layer 6 is of i-type, electron mobility is high, which results in a low resistance between the source electrode 10 and the drain electrode 20. The semiconductor device in FIG. 1 is a field-effect transistor adjusted to have normally-off characteristics.

In FIG. 1, reference number 12 denotes an insulation layer covering the surface of the electron supply layer 8 exposed between the source electrode 10 and the p-type layer 16, and reference number 18 denotes an insulation layer covering the surface of the electron supply layer 8 exposed between the drain electrode 20 and the p-type layer 16. The insulation layers 12, 18 have positive charges fixed therein, in other words, are positively charged. Since the insulation layers 12, 18 are positively charged, electrons are attracted to the hetero junction interface in a range opposite to the insulation layers 12, 18, and a concentration of the two-dimensional electron gas generated at the hetero junction interface in the range opposite to the insulation layers 12, 18 accordingly becomes high. A resistance of the hetero junction interface between the source electrode 10 and the p-type layer 16 is therefore low, and a resistance of the hetero junction interface between the drain electrode 20 and the p-type layer 16 is low. A resistance (on-resistance) between the source electrode 10 and the drain electrode 20 when a positive voltage is applied to the gate electrode is low.

The p-type layer 16 is manufactured by a method described below. Initially, a p-type wide-region layer is provided on a surface of an electron supply layer 8 in a wide range. Next, the p-type wide-region layer is etched and removed between the p-type layer 16 and the source electrode 10 in FIG. 1, and between the p-type layer 16 and the drain electrode 20 in FIG. 1. Consequently, the p-type layer 16 shown in FIG. 1 is provided. When the p-type wide-region layer is etched between the p-type layer 16 and the source electrode 10 shown in FIG. 1, and between the p-type layer 16 and the drain electrode 20 shown in FIG. 1, an etching damage is exerted on the surface of the electron supply layer 8 exposed between the p-type layer 16 and the source electrode 10 shown in FIG. 1, and exposed between the p-type layer 16 and the drain electrode 20 shown in FIG. 1. The etching damage causes a decrease in concentration of the two-dimensional electron gas generated at the hetero junction interface. In the semiconductor device in FIG. 1, the effect of the etching damage that causes a decrease in concentration of the two-dimensional electron gas can be compensated for by the effect of the positively charged insulation layers 12, 18 that causes an increase in concentration of the two-dimensional electron gas, and the on-resistance can be decreased. The semiconductor device in FIG. 1 achieves an extremely low on-resistance because the effect of the positively charged insulation layers 12, 18 that causes an increase in concentration of the two-dimensional electron gas is combined with the fact that the electron transport layer 6, which allows electrons to be transported, is of i-type.

### Second Embodiment

As shown in FIG. 2, a portion of an exposed region of an electron supply layer 8 that is exposed between the drain electrode 20 and the p-type layer 16 may be covered by a positively charged insulation layer 18b, and another portion of the exposed region may be covered by an insulation layer 18a that is not positively charged. In this case, a drain electrode 20 side of the electron supply layer 8 is covered by the insulation layer 18b where the positive charges are fixed, and a p-type layer 16 side of the electron supply layer 8 is covered by the insulation layer 18a where the positive charges are not fixed. In this case, on-resistance is decreased in the drain electrode 20 side covered by the positively charged insulation layer 18b. On the other hand, a high withstand voltage and a low resistance are realized in a vicinity of the gate electrode 14, as an electric field in a depletion layer that extends from the gate electrode 14 side toward the drain electrode 20 side during an off state is considerably relaxed. In FIG. 2, there exists a relation in which the distance between the source electrode 10 and the p-type layer 16<the distance between the drain electrode 20 and the p-type layer 16, and the technology in which a part of the region of the electron supply layer 8 is covered by the positively charged insulation layer is applied only in the drain electrode 20 side. It is also possible to utilize this technology for the source electrode side.

### Third Embodiment

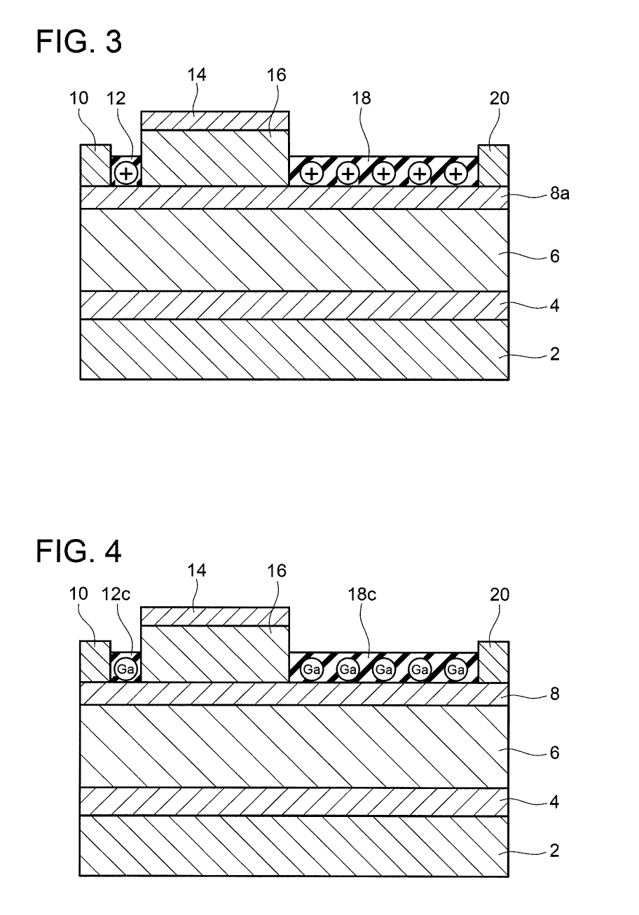

As shown in FIG. 3, it is possible to decrease a concentration of Al in AlGaN that forms an electron supply layer 8a to thereby set a high threshold voltage. This is useful for preventing malfunction. However, if the Al concentration is decreased, e.g., by setting y1 of Al_{y1}Ga_{1-y1}N to be equal to or less than 0.1, the concentration of the two-dimensional electron gas generated at the hetero junction interface is decreased, and an on-resistance is increased. The present embodiment is for coping with this problem, and uses positively charged insulation layers 12, 18 to decrease the on-resistance. The present technology is useful particularly in the case where the concentration of Al in AlGaN that forms the electron supply layer 8a is decreased to thereby set a high threshold voltage.

### Fourth Embodiment

FIG. 4 shows a fourth embodiment, which uses an SiO₂ layer where Ga ions are contained in a dispersed form, as insulation layers 12c, 18c. The Ga ions have positive charges and the insulation layers 12c, 18c are positively charged. This SiO₂ layer is formed by SiO₂ being deposited on a surface of an electron supply layer 8 by a thermal CVD method. As a temperature at which the thermal CVD method is performed is increased, an amount of Ga, which is contained in the electron supply layer 8 and moves into SiO₂, increases. It is possible to form the positively charged insulation layers 12c, 18c by performing the thermal CVD method at a temperature that allows Ga to move in an amount that corresponds to a necessary charge amount. It is also possible by a plasma CVD method to form the SiO₂ layer where Ga ions are in a dispersed form. Na positive ions or Ga positive ions may be implanted, for example, into insulation layers that contain no positive ions. Na ions, Ga ions, or the like have difficulty in moving in the insulation layers, and hence the insulation layers where the positive charges are fixed are obtained.

While specific examples of the present invention have been described above in detail, these examples are merely illustrative and place no limitation on the scope of the patent claims. The technology described in the patent claims also encompasses various changes and modifications to the specific examples described above. The technical elements explained in the present description or drawings provide technical utility either independently or through various combinations. The present invention is not limited to the combinations described at the time the claims are filed. Further, the purpose of the examples illustrated by the present description or drawings is to satisfy multiple objectives simultaneously, and satisfying any one of those objectives gives technical utility to the present invention.

What is claimed is:

1. A semiconductor device comprising:
a hetero junction structure including an electron transport layer of GaN and an electron supply layer of Inₓ₁Al_{y1}Ga_{1-x1-y1}N (0≦x1≦1, 0≦y1≦1, 0≦1−x1−y1<1);
a source electrode provided above a surface of the electron supply layer;
a drain electrode provided above the surface of the electron supply layer, the drain electrode being spaced from the source electrode;
a p-type layer of Inₓ₂Al_{y2}Ga_{1-x2-y2}N (0≦x2≦1, 0≦y2≦1, 0≦1−x2−y2≦1) provided above the surface of the electron supply layer and between the source electrode and the drain electrode;
a gate electrode being in electrical contact with the p-type layer; and
an insulation layer covering at least one of the surface of the electron supply layer exposed between the source electrode and the p-type layer and the surface of the electron supply layer exposed between the drain electrode and the p-type layer, wherein positive charges are fixed in at least a part of the insulation layer.

2. The semiconductor device according to claim 1, wherein
positive charges are fixed in a drain electrode side and are not fixed in a p-type layer side, of the insulation layer covering the surface of the electron supply layer exposed between the drain electrode and the p-type layer.

3. The semiconductor device according to claim 1, wherein
Gallium are in a dispersed form within the insulation layer.

4. A method of manufacturing a semiconductor device according to claim 1, the method comprising:
forming a p-type wide-region layer of Inₓ₂Al_{y2}Ga_{1-x2-y2}N (0≦x2≦1, 0≦y2≦1, 0≦1−x2−y2≦1) above a surface of the electron supply layer;
etching a part of the p-type wide-region layer to expose the surface of the electron supply layer such that the p-type layer is formed above the surface of the electron supply layer; and
forming the insulation layer covering at least one of the surface of the electron supply layer exposed between the source electrode and the p-type layer and the surface of the electron supply layer exposed between the drain electrode and the p-type layer.
